(19) United States
(12) Patent Application Publication
(10) Pub. No.: US 2015/0162551 A1
(43) Pub. Date: Jun. 11, 2015

(54) LIGHT-EMITTING COMPOUND

(71) Applicants: Cambridge Display Technology Limited, Godmanchester (GB); Sumitomo Chemical Company Limited, Tokyo (JP)

(72) Inventor: Annette Steudel, Dresden (DE)

(73) Assignees: Cambridge Display Technology Limited, Godmanchester (GB); Sumitomo Chemical Company Limited, Tokyo (JP)

(21) Appl. No.: 14/550,794

(22) Filed: Nov. 21, 2014

(30) Foreign Application Priority Data
Nov. 29, 2013 (GB) 1321096.8

(51) Int. Cl. H01L 51/00; C09K 11/06; C07F 15/00

(52) U.S. Cl. CPC H01L 51/0085; H01L 51/0067; H01L 51/0054; C07F 15/0033; C09K 11/06; H01L 51/5016

(57) ABSTRACT

A phosphorescent compound of formula (I):

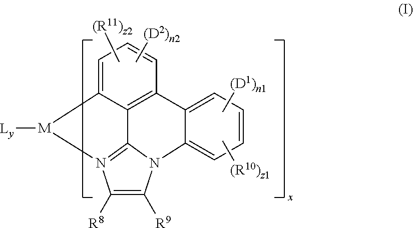

wherein:
M is a transition metal; L in each occurrence is independently a mono- or poly-dentate ligand; R⁸, R⁹, R¹⁰ and R¹¹ are each independently H or a substituent; D¹ and D² are each independently a dendron; x is at least 1; y is 0 or a positive integer; z1 and z2 are each independently 0 or a positive integer; and n1 and n2 are each independently 0 or 1 with the proviso that at least one of n1 and n2 is 1. The compound may be a phosphorescent compound of an organic light-emitting device.

### RELATED APPLICATIONS

Foreign priority benefits are claimed under 35 U.S.C. §119(a)-(d) or 35 U.S.C. §365(b) of British application number 1321096.8, filed Nov. 29, 2013, the entirety of which is incorporated herein by reference.

### FIELD OF THE INVENTION

The present invention relates to light-emitting compounds, in particular phosphorescent light-emitting compounds; compositions, solutions and light-emitting devices comprising said light-emitting compounds; and methods of making said light-emitting devices.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

Suitable light-emitting materials include small molecule, polymeric and dendrimeric materials. Suitable light-emitting polymers include poly(arylene vinylenes) such as poly(p-phenylene vinylenes) and polyarylenes such as polyfluorenes.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

WO 02/066552 discloses dendrimers having a metal complex core.

WO 2010/032663 discloses iridium complexes having imidazo-phenanthridine ligands, for example compounds having the following structure:

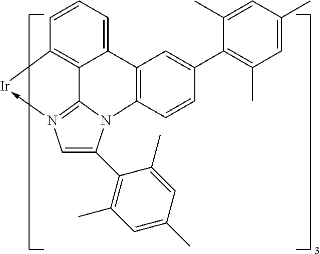

US 2007190359 discloses phosphorescent metal complexes comprising cyclometallated imidazo[1,2-f]phenanthridine and diimidazo[1,2-a:1′,2′-c]quinazoline ligands, or isoelectronic or benzannulated analogs thereof.

It is an object of the invention to provide blue phosphorescent light-emitting compounds suitable for use in an OLED.

It is a further object of the invention to provide solution processable blue phosphorescent light-emitting compounds suitable for use in an OLED.

It is a further objection of the invention to provide phosphorescent light-emitting compounds having long operational life when used in an OLED.

### SUMMARY OF THE INVENTION

In a first aspect the invention provides a phosphorescent compound of formula (I):

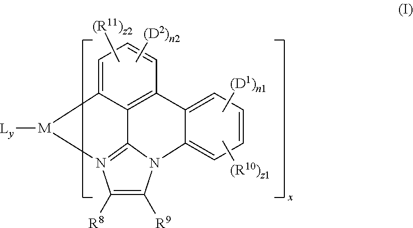

wherein:
M is a transition metal;
L in each occurrence is independently a mono- or poly-dentate ligand;
R⁸, R⁹, R¹⁰ and R¹¹ are each independently H or a substituent;
D¹ and D² are each independently a dendron;
x is at least 1;
y is 0 or a positive integer;
z1 and z2 are each independently 0 or a positive integer; and
n1 and n2 are each independently 0 or 1 with the proviso that at least one of n1 and n2 is 1.

In a second aspect the invention provides a composition comprising a host material and a compound according to the first aspect.

In a third aspect the invention provides a solution comprising a compound of the first aspect or composition of the second aspect dissolved in one or more solvents.

In a fourth aspect the invention provides an organic light-emitting device comprising an anode, a cathode and a light-emitting layer between the anode and cathode wherein the light-emitting layer comprises a compound or composition according to the first or second aspect.

In a fifth aspect the invention provides a method of forming an organic light-emitting device according to the fourth aspect, the method comprising the step of depositing the light-emitting layer over one of the anode and cathode, and depositing the other of the anode and cathode over the light-emitting layer.

Optionally according to the fifth aspect, the light-emitting layer is formed by depositing a solution according to the third aspect and evaporating the one or more solvents.

### DESCRIPTION OF THE DRAWINGS

The invention will now be described in more detail with reference to the Figures, in which:

FIG. 1 illustrates an OLED according to an embodiment of the invention; and

FIG. 2 shows the electroluminescence spectra for a white OLED according to an embodiment of the invention and a comparative white OLED.

### DETAILED DESCRIPTION OF THE INVENTION

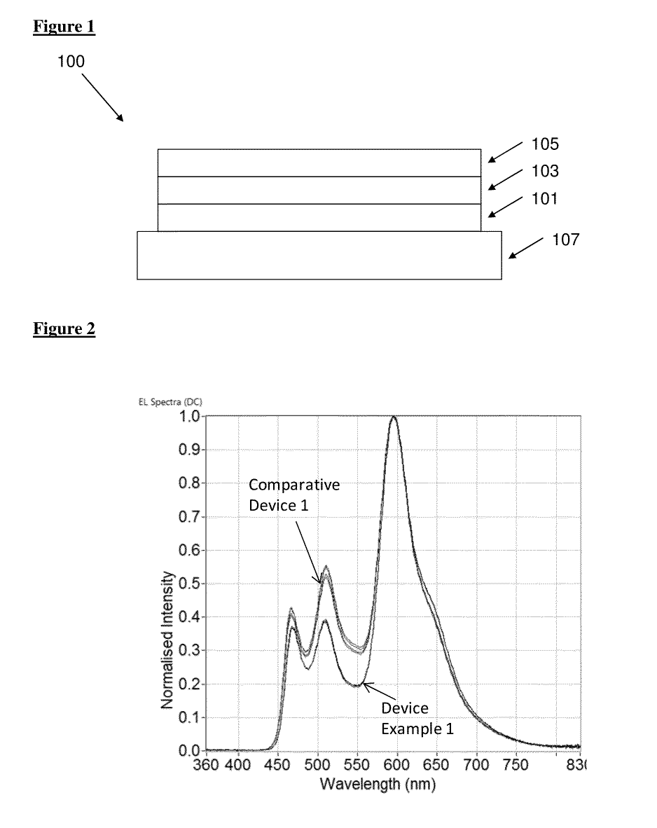

FIG. 1, which is not drawn to any scale, illustrates schematically an OLED 100 according to an embodiment of the invention. The OLED 100 is carried on substrate 107 and comprises an anode 101, a cathode 105 and a light-emitting layer 103 between the anode and the cathode. Further layers (not shown) may be provided between the anode and the cathode including, without limitation, hole-transporting layers, electron-transporting layers, hole-blocking layers, electron-blocking layers, hole-injection layers and electron-injection layers.

Exemplary OLED structures including one or more further layers include the following:

Anode/Hole-injection layer/Light-emitting layer/Cathode
Anode/Hole transporting layer/Light-emitting layer/Cathode
Anode/Hole-injection layer/Hole-transporting layer/Light-emitting layer/Cathode
Anode/Hole-injection layer/Hole-transporting layer/Light-emitting layer/Electron-transporting layer/Cathode.

Light-emitting layer 103 may contain a host material and a phosphorescent compound of formula (I). The host material may combine holes injected from the anode and electrons injected from the cathode to form singlet and triplet excitons. The triplet excitons at least may be transferred to the phosphorescent compound of formula (I), and decay to produce phosphorescence.

The device may contain more than one light-emitting layer. The light-emitting layer or layers may contain the phosphorescent compound of formula (I) and one or more further light-emitting compounds, for example further phosphorescent or fluorescent light-emitting materials having a colour of emission differing from that of the compound of formula (I). Emission from the compound of formula (I) and the further light-emitting compounds may produce white light when the device is in use.

Preferably, light emitted from a composition of a host and a compound of formula (I) is substantially all from the compound of formula (I).

### Phosphorescent Compound

Metal M of the phosphorescent compound of formula (I) may be any suitable transition metal, for example a transition metal of the second or third row of the d-block elements (Period 5 and Period 6, respectively, of the Periodic Table). Exemplary metals include Ruthenium, Rhodium, Palladium, Silver, Tungsten, Rhenium, Osmium, Iridium, Platinum and Gold. Preferably, M is iridium.

Compounds of formula (I) have a core unit CORE:

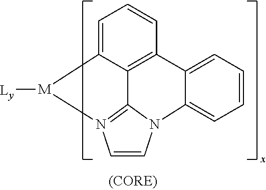

The imidazo[1,2-f]phenanthridine ligand (or ligands if x is greater than 1) of the compound of formula (I) is substituted with at least one of a dendron D1 and a dendron D2.

Dendrons D1 and D2 each have an aromatic or heteroaromatic branching point that is bound to the imidazo[1,2-f]phenanthridine ligand(s) of formula (I). The branching point is substituted with at least two first generation branching groups G₁ to form a first generation dendron.

The first generation dendron may have optionally substituted formula (II)

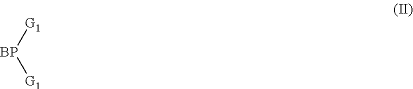

wherein BP represents an aromatic or heteroaromatic branching point that is bound to CORE and G₁ represents first generation branching groups.

The dendron may be a first, second, third or higher generation dendron. G₁ may be substituted with two or more second generation branching groups G₂, and so on, up to generation n having branching groups Gn.

A first, second or third generation dendron may have formula (III):

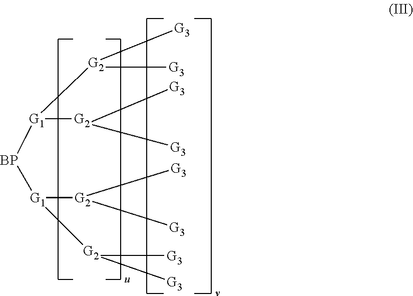

wherein u is 0 or 1; v is 0 if u is 0 or may be 0 or 1 if u is 1; BP represents the branching point for attachment to CORE and G₁, G₂ and G₃ represent first, second and third generation dendron branching groups.

For simplicity, Figure (III) illustrates a dendron structure up to and including a third generation dendron, although it will be appreciated that dendrons D1 and/or D2 may be of a higher generation.

Figure (III) illustrates a dendron structure with two branches extending from the branching point BP and each branching group, although it will be appreciated BP and/or one or more branching groups may have more than two branches.

Branching point BP and each branching group G₁, G₂ . . . Gₙ may each be an aromatic group; a heteroaromatic group; an arylenevinylene group; or a heteroarylenevinylene group. N-containing heteroaryls are preferred in the case where a branching point or branching group is a heteroaromatic group or a heteroarylenevinylene group.

In one embodiment, each of BP and G₁, G₂ . . . Gₙ is phenyl, and each phenyl BP, G₁, G₂ . . . Gₙ₋₁ is a 3,5-linked phenyl.

In one preferred embodiment, BP is triazine and G₁, G₂ . . . Gₙ is phenyl, and each phenyl BP, G₁, G₂ . . . Gₙ₋₁ is a 3,5-linked phenyl.

Exemplary dendrons are illustrated below:

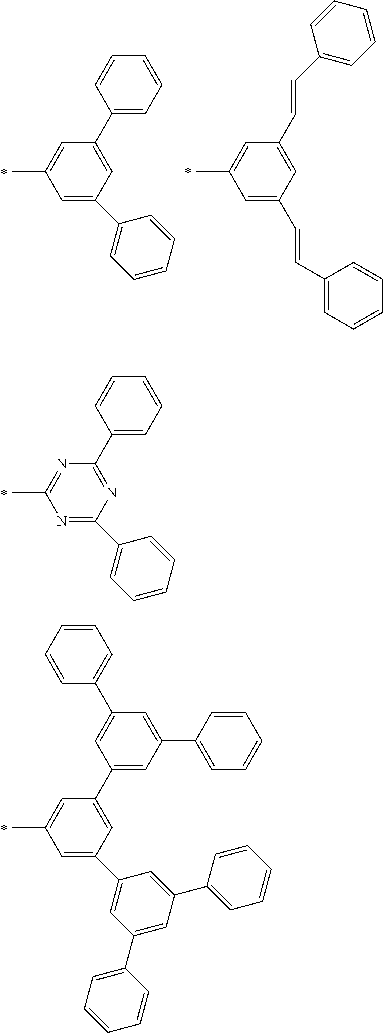

wherein * represents an attachment point of the dendron to CORE.

Any group G may be substituted with one or more substituents. Exemplary substituents may be selected from F, CN, and branched, linear or cyclic C₁₋₂₀ alkyl wherein non-adjacent C atoms of the C₁₋₂₀ alkyl may be replaced with —O—, —S—, —NR³—, —SiR³₂- or —COO— and one or more H atoms may be replaced with F, wherein R³ is H or a substituent. R³ may be a C₁₋₄₀ hydrocarbyl group, for example C₁₋₂₀ alkyl, unsubstituted phenyl, and phenyl substituted with one or more C₁₋₂₀ alkyl groups.

Optionally, one or more branching groups of the last generation of branching groups Gn is substituted to provide the dendron with surface substituents.

In addition to substitution with dendrons D1 and/or D2, CORE may be substituted with one or more substituents R⁸, R⁹, R¹⁰ and R¹¹.

R⁸ and R⁹ may each independently be selected from the group consisting of:

H;

aryl or heteroaryl that may be unsubstituted or substituted with one or more substituents, for example unsubstituted phenyl or phenyl substituted with one or more C₁₋₂₀ alkyl or C₁₋₂₀ alkoxy groups; branched, linear or cyclic C₁₋₂₀ alkyl wherein non-adjacent C atoms of the C₁₋₂₀ alkyl may be replaced with —O—, —S—, —NR³—, —SiR³₂- or —COO— and one or more H atoms may be replaced with F, wherein R³ is H or a substituent. R³ may be a C₁₋₄₀ hydrocarbyl group, for example C₁₋₂₀ alkyl, unsubstituted phenyl, and phenyl substituted with one or more C₁₋₂₀ alkyl groups; and
a dendron, for example a dendron as described with reference to D1 or D2. R⁹ and R¹⁰ may each independently be selected from the group consisting of:
aryl or heteroaryl that may be unsubstituted or substituted with one or more substituents, for example unsubstituted phenyl or phenyl substituted with one or more C₁₋₂₀ alkyl or C₁₋₂₀ alkoxy groups; and
branched, linear or cyclic C₁₋₂₀ alkyl wherein non-adjacent C atoms of the C₁₋₂₀ alkyl may be replaced with —O—, —S—, —NR³—, —SiR³₂- or —COO— and one or more H atoms may be replaced with F, wherein R³ is H or a substituent. R³ may be a C₁₋₄₀ hydrocarbyl group, for example C₁₋₂₀ alkyl, unsubstituted phenyl, and phenyl substituted with one or more C₁₋₂₀ alkyl groups.

Optionally, at least one of R⁸ and R⁹ is a substituent.

Optionally, z1 and z2 are both 0.

If R⁸, R⁹, R¹⁰ or R¹¹ is an aryl or heteroaryl group, for example phenyl, then the aryl or heteroaryl group may be substituted at one or both positions adjacent to the position linking it to CORE to create a twist between CORE and R⁸ or R⁹ which may limit the extent of conjugation between the aryl or heteroaryl and the imidazophenanthridine ligand of CORE. Limiting the extent of this conjugation may limit a shift towards a longer wavelength that such a substituent may otherwise cause.

The metal complex of formula (I) may be homoleptic complex in which the value of x satisfies the valency of the metal M, or a heteroleptic complex.

In the case where the metal complex is heteroleptic, the ligands may differ in one or more of:
(i) the groups directly coordinated to metal M;
(ii) the number of substituents on the coordinating groups;
(iii) the position of substituents on the coordinating groups; and
(iv) the structure of substituents on the coordinating groups.
   y of formula (I) may be 0 or a positive integer. If y=0 then x may be 3.

A heteroleptic complex may contain two or more imidazophenanthridine ligands substituted with different substituents.

If y is a positive integer then exemplary ligands L of formula (I) include unsubstituted phenyltriazole, or phenyltriazole substituted with one or more C₁₋₂₀ alkyl groups, unsubstituted phenylimidazole or phenylimidazole substituted with one or more C₁₋₂₀ alkyl groups, unsubstituted phenylpyrazole or phenylpyrazole substituted with one or more C₁₋₂₀ alkyl groups, and unsubstituted imidazo-phenanthridine or imidazo-phenanthridine substituted with one or more C₁₋₂₀ alkyl groups and ancillary ligands, for example tetrakis-(pyrazol-1-yl)borate, 2-carboxypyridyl and diketonates, for example acetylacetonate.

Exemplary compounds of formula (I) include the following:

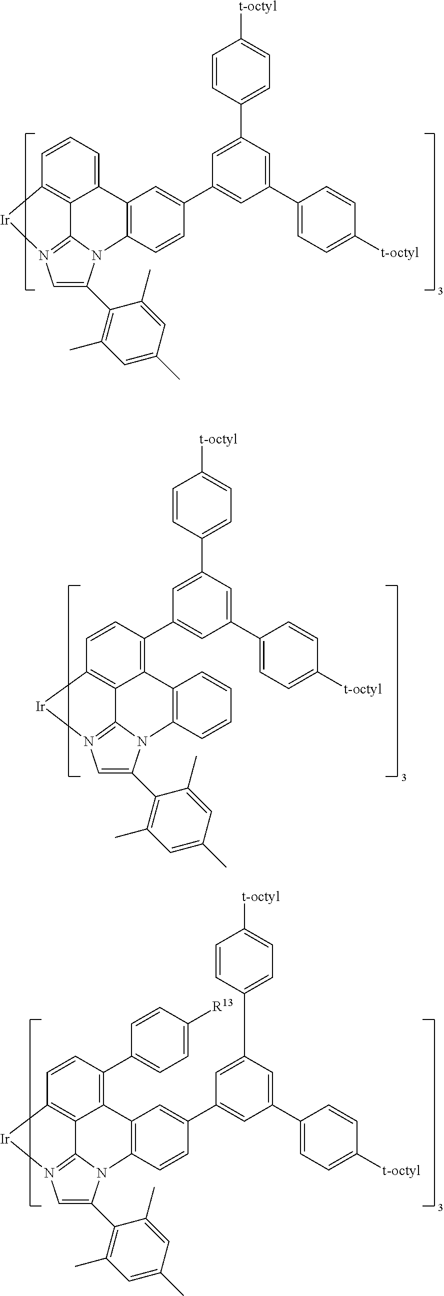

wherein t-octyl has the following structure, wherein * represents the point of attachment of the t-octyl substituent:

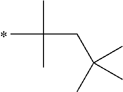

Compounds of formula (I) preferably have a photoluminescence spectrum with a peak in the range of 400-490 nm, optionally 420-490 nm, optionally 460-480 nm.

### Host Material

The host material has a triplet excited state energy level T₁ that is no more than 0.1 eV lower than, and preferably at least the same as or higher than, the phosphorescent compound of formula (I) in order to allow transfer of triplet excitons from the host material to the phosphorescent compound of formula (I).

The triplet excited state energy levels of the host material and the phosphorescent compound may be determined from their respective phosphorescence spectra.

The host material may be a polymer or a non-polymeric compound.

An exemplary non-polymeric host material is an optionally substituted compound of formula (X):

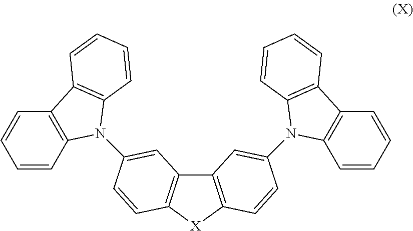

wherein X is O or S.

Each of the benzene rings of the compound of formula (X) may independently be unsubstituted or substituted with one or more substituents. Substituents may be selected from C₁₋₂₀ alkyl wherein one or more non-adjacent C atoms of the alkyl may be replaced with O, S, COO, C═O or Si, and one or more H atoms of the alkyl may be replaced with F.

The compound of formula (I) may be blended with the host material or may be covalently bound to the host material. In the case where the host material is a polymer, the metal complex may be provided as a main chain repeat unit, a side group of a repeat unit, or an end group of the polymer.

In the case where the compound of formula (I) is provided as a side group, the metal complex may be directly bound to a main chain of the polymer or spaced apart from the main chain by a spacer group. Exemplary spacer groups include C₁₋₂₀ alkyl groups, aryl-C₁₋₂₀ alkyl groups and C₁₋₂₀ alkoxy groups. The polymer main chain or spacer group may be bound to phenyltriazole; or (if present) another ligand of the compound of formula (I).

If the compound of formula (I) is bound to a polymer comprising conjugated repeat units then it may be bound to the polymer such that there is no conjugation between the conjugated repeat units and the compound of formula (I), or such that the extent of conjugation between the conjugated repeat units and the compound of formula (I) is limited.

If the compound of formula (I) is mixed with a host material then the host:emitter weight ratio may be in the range of 50-99.5:50-0.5.

If the compound of formula (I) is bound to a polymer then repeat units or end groups containing a compound of formula (I) may form 0.5-20 mol percent, more preferably 1-10 mol percent of the polymer.

Exemplary host polymers include polymers having a non-conjugated backbone with charge-transporting groups pendant from the non-conjugated backbone, for example poly(9-vinylcarbazole), and polymers comprising conjugated repeat units in the backbone of the polymer. If the backbone of the polymer comprises conjugated repeat units then the extent of conjugation between repeat units in the polymer backbone may be limited in order to maintain a triplet energy level of the polymer that is no lower than that of the phosphorescent compound of formula (I).

Exemplary repeat units of a conjugated polymer include unsubstituted or substituted monocyclic and polycyclic heteroarylene repeat units; unsubstituted or substituted monocyclic and polycyclic arylene repeat units as disclosed in for example, Adv. Mater. 2000 12(23) 1737-1750 and include: 1,2-, 1,3- and 1,4-phenylene repeat units as disclosed in J. Appl. Phys. 1996, 79, 934; 2,7-fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

One exemplary class of repeat units are unsubstituted or substituted repeat units of formula (IV):

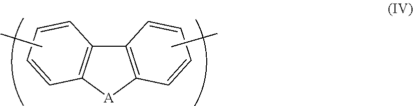

wherein A is O, S, NR¹, CR¹₂, or SiR¹₂; R¹ in each occurrence is the same or different and is H or a substituent, and wherein the two groups R¹ may be linked to form a ring.

Each R¹ is preferably a substituent, and each R¹ may independently be selected from the group consisting of:
optionally substituted alkyl, optionally C₁₋₂₀ alkyl, wherein one or more non-adjacent C atoms may be replaced with optionally substituted aryl or heteroaryl, O, S, substituted N, C═O or —COO—;
optionally substituted aryl or heteroaryl;
a linear or branched chain of aryl or heteroaryl, each of which groups may independently be substituted, for example a group of formula —(Ar⁶)ᵣ as described below with reference to formula (VI); and
a crosslinkable-group, for example a group comprising a double bond such and a vinyl or acrylate group, or a benzocyclobutene group.

In the case where R¹ comprises aryl or heteroaryl ring system, or a linear or branched chain of aryl or heteroaryl ring systems, the or each aryl or heteroaryl ring system may be substituted with one or more substituents R³ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵, and
fluorine, nitro and cyano;
   wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

Aromatic carbon atoms of the repeat unit of formula (IV) may be unsubstituted or substituted with one or more substituents. Substituents may be selected from the group consisting of alkyl, for example C₁₋₂₀ alkyl, wherein one or more non-adjacent C atoms may be replaced with O, S, NH or substituted N, C═O and —COO—, optionally substituted aryl, optionally substituted heteroaryl, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

Where present, substituted N may independently in each occurrence be NR⁶ wherein R⁶ is alkyl, optionally C₁₋₂₀ alkyl, or optionally substituted aryl or heteroaryl. Optional substituents for aryl or heteroaryl R⁶ may be selected from R⁴ or R⁵.

Preferably, each R¹ is selected from the group consisting of C₁₋₂₀ alkyl and optionally substituted phenyl. Optional substituents for phenyl include one or more C₁₋₂₀ alkyl groups.

If the compound of formula (I) is provided as a side-chain of the polymer then A may be NR¹, CR¹₂, or SiR¹₂ and at least one R¹ may comprise a compound of formula (I) that is either bound directly to N, C or Si or spaced apart from A by a spacer group.

The extent of conjugation of repeat units of formulae (IV) may be limited by (a) selecting the linking positions of the repeat unit and/or (b) substituting one or more aromatic carbon atoms adjacent to linking positions of the repeat unit in order to create a twist with the adjacent repeat unit or units, for example a 2,7-linked fluorene carrying a C₁₋₂₀ alkyl substituent in one or both of the 3- and 6-positions.

Exemplary repeat units of formula (IV) include the following:

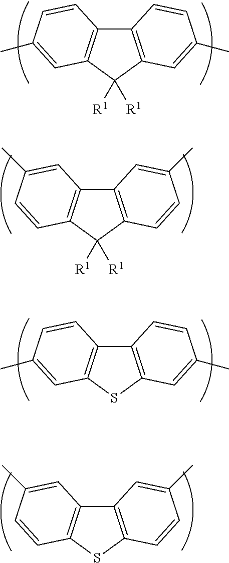

A host polymer may contain one repeat unit of formula (IV) or two or more different repeat units of formula (IV).

Another exemplary class of repeat units is phenylene repeat units, such as phenylene repeat units of formula (V):

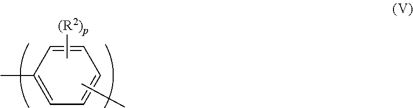

wherein p is 0, 1, 2, 3 or 4, optionally 1 or 2, and R² independently in each occurrence is a substituent, optionally a substituent R¹ as described above, for example C₁₋₂₀ alkyl, and phenyl that is unsubstituted or substituted with one or more C₁₋₂₀ alkyl groups.

The repeat unit of formula (V) may be 1,4-linked, 1,2-linked or 1,3-linked.

If the repeat unit of formula (V) is 1,4-linked and if p is 0 then the extent of conjugation of repeat unit of formula (V) to one or both adjacent repeat units may be relatively high.

If p is at least 1, and/or the repeat unit is 1,2- or 1,3 linked, then the extent of conjugation of repeat unit of formula (V) to one or both adjacent repeat units may be relatively low. In one preferred arrangement, the repeat unit of formula (V) is 1,3-linked and p is 0, 1, 2 or 3. In another preferred arrangement, the repeat unit of formula (V) has formula (Va):

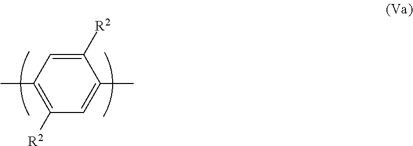

Arylene repeat units such as repeat units of formula (IV) and (V) may be fully conjugated with aromatic or heteroaromatic group of adjacent repeat units. Additionally or alternatively, a host polymer may contain a conjugation-breaking repeat unit that completely breaks conjugation between repeat units adjacent to the conjugation-breaking repeat unit. An exemplary conjugation-breaking repeat unit has formula (IX):

—(Ar⁷-Sp¹-Ar⁷)— (IX)

wherein Ar⁷ independently in each occurrence represents an aromatic or heteroaromatic group that may be unsubstituted or substituted with one or more substituents, and Sp¹ represents a spacer group comprising at least one sp³ hybridised carbon atom separating the two groups Ar⁷. Preferably, each Ar⁷ is phenyl and Sp¹ is a C₁₋₁₀ alkyl group. Substituents for Ar⁷ may be selected from groups R² described above with reference to formula (V), and are preferably selected from C₁₋₂₀ alkyl.

A host polymer may comprise charge-transporting units CT that may be hole-transporting units or electron transporting units.

A hole transporting unit may have a low electron affinity (2 eV or lower) and low ionisation potential (5.8 eV or lower, preferably 5.7 eV or lower, more preferred 5.6 eV or lower).

An electron-transporting unit may have a high electron affinity (1.8 eV or higher, preferably 2 eV or higher, even more preferred 2.2 eV or higher) and high ionisation potential (5.8 eV or higher) Suitable electron transport groups include groups disclosed in, for example, Shirota and Kageyama, Chem. Rev. 2007, 107, 953-1010.

Electron affinities and ionisation potentials may be measured by cyclic voltammetry (CV). The working electrode potential may be ramped linearly versus time.

When cyclic voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinum counter electrode (donor or acceptor of electrons) and a reference glass electrode no leak Ag/AgCl. Ferrocene is added in the cell at the end of the experiment for calculation purposes. (Measurement of the difference of potential between Ag/AgCl/ferrocene and sample/ferrocene).

### Method and Settings:

3 mm diameter glassy carbon working electrode
Ag/AgCl/no leak reference electrode
Pt wire auxiliary electrode
0.1 M tetrabutylammonium hexafluorophosphate in acetonitrile
LUMO=4.8−ferrocene (peak to peak maximum average)+onset
Sample: 1 drop of 5 mg/mL in toluene spun @3000 rpm LUMO (reduction) measurement: A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline.

Exemplary hole-transporting units CT include optionally substituted (hetero)arylamine repeat units, for example repeat units of formula (VI):

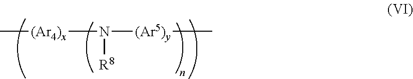

wherein Ar⁴ and Ar⁵ in each occurrence are independently selected from optionally substituted aryl or heteroaryl, n is greater than or equal to 1, preferably 1 or 2, R⁸ is H or a substituent, preferably a substituent, and x and y are each independently 1, 2 or 3.

Ar⁴ and Ar⁵ may each independently be a monocyclic or fused ring system.

R⁸, which may be the same or different in each occurrence when n>1, is preferably selected from the group consisting of alkyl, for example C₁₋₂₀ alkyl, Ar⁶, a branched or linear chain of Ar⁶ groups, or a crosslinkable unit that is bound directly to the N atom of formula (VI) or spaced apart therefrom by a spacer group, wherein Ar⁶ in each occurrence is independently optionally substituted aryl or heteroaryl. Exemplary spacer groups are as described above, for example C₁₋₂₀ alkyl, phenyl and phenyl-C₁₋₂₀ alkyl.

Ar⁶ groups may be substituted with one or more substituents as described below. An exemplary branched or linear chain of Ar⁶ groups may have formula —(Ar⁶)ᵣ, wherein Ar⁶ in each occurrence is independently selected from aryl or heteroaryl and r is at least 1, optionally 1, 2 or 3. An exemplary branched chain of Ar⁶ groups is 3,5-diphenylbenzene.

Any of Ar⁴, Ar⁵ and Ar⁶ may independently be substituted with one or more substituents. Preferred substituents are selected from the group R³ consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵,
fluorine, nitro and cyano;
   wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

Any two of Ar⁴, Ar⁵ and, if present, Ar⁶ bound directly to the same N atom in the repeat unit of Formula (VI) may be linked by a direct bond or a divalent linking atom or group. Preferred divalent linking atoms and groups include O, S; substituted N; and substituted C.

Where present, substituted N or substituted C of R³, R⁴ or of the divalent linking group may independently in each occurrence be NR⁶ or CR⁶₂ respectively wherein R⁶ is alkyl or optionally substituted aryl or heteroaryl. Optional substituents for aryl or heteroaryl R⁶ may be C₁₋₂₀ alkyl.

In one preferred arrangement, R⁸ is Ar⁶ and each of Ar⁴, Ar⁵ and Ar⁶ are independently and optionally substituted with one or more C₁₋₂₀ alkyl groups.

Particularly preferred units satisfying Formula (VI) include units of Formulae 1-4:

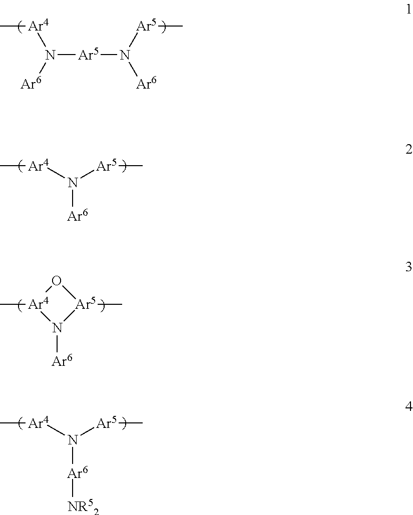

Where present, preferred substituents for Ar⁶ include substituents as described for Ar⁴ and Ar⁵, in particular alkyl and alkoxy groups.

Ar⁴, Ar⁵ and Ar⁶ are preferably phenyl, each of which may independently be substituted with one or more substituents as described above.

In another preferred arrangement, Ar⁴, Ar⁵ and Ar⁶ are phenyl, each of which may be substituted with one or more C₁₋₂₀ alkyl groups, and r=1.

In another preferred arrangement, Ar⁴ and Ar⁵ are phenyl, each of which may be substituted with one or more C₁₋₂₀ alkyl groups, and R⁸ is 3,5-diphenylbenzene wherein each phenyl may be substituted with one or more C₁₋₂₀ alkyl groups.

In another preferred arrangement, n, x and y are each 1 and Ar⁴ and Ar⁵ are phenyl linked by an oxygen atom to form a phenoxazine ring.

Triazines form an exemplary class of electron-transporting units, for example optionally substituted di- or tri-(hetero)aryltriazine attached as a side group through one of the (hetero)aryl groups. Other exemplary electron-transporting units are pyrimidines and pyridines; sulfoxides and phosphine oxides; benzophenones; and boranes, each of which may be unsubstituted or substituted with one or more substituents, for example one or more C₁₋₂₀ alkyl groups.

Exemplary electron-transporting units CT have formula (VII):

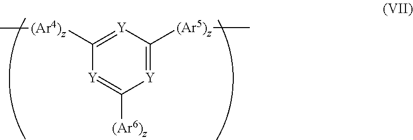

wherein Ar⁴, Ar⁵ and Ar⁶ are as described with reference to formula (VI) above, and may each independently be substituted with one or more substituents described with reference to Ar⁴, Ar⁵ and Ar⁶, and z in each occurrence is independently at least 1, optionally 1, 2 or 3 and Y is N or CR⁷, wherein R⁷ is H or a substituent, preferably H or C₁₋₁₀ alkyl. Preferably, Ar⁴, Ar⁵ and Ar⁶ of formula (VII) are each phenyl, each phenyl being optionally and independently substituted with one or more C₁₋₂₀ alkyl groups.

In one preferred embodiment, all 3 groups Y are N.

If all 3 groups Y are CR⁷ then at least one of Ar¹, Ar² and Ar^{a} is preferably a hetero aromatic group comprising N.

Each of Ar⁴, Ar⁵ and Ar⁶ may independently be substituted with one or more substituents. In one arrangement, Ar⁴, Ar⁵ and Ar⁶ are phenyl in each occurrence. Exemplary substituents include R³ as described above with reference to formula (VI), for example C₁₋₂₀ alkyl or alkoxy.

Ar⁶ of formula (VII) is preferably phenyl, and is optionally substituted with one or more C₁₋₂₀ alkyl groups or a crosslinkable unit. The crosslinkable unit may or may not be a unit of formula (I) bound directly to Ar⁶ or spaced apart from Ar⁶ by a spacer group.

The charge-transporting units CT may be provided as distinct repeat units formed by polymerising a corresponding monomer. Alternatively, the one or more CT units may form part of a larger repeat unit, for example a repeat unit of formula (VIII):

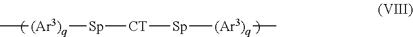

wherein CT represents a conjugated charge-transporting group; each Ar³ independently represents an unsubstituted or substituted aryl or heteroaryl; q is at least 1; and each Sp independently represents a spacer group forming a break in conjugation between Ar³ and CT.

Sp is preferably a branched, linear or cyclic C₁₋₂₀ alkyl group.

Exemplary CT groups include units of formula (VI) or (VII) described above.

Ar³ is preferably an unsubstituted or substituted aryl, optionally an unsubstituted or substituted phenyl or fluorene. Optional substituents for Ar³ may be selected from R³ as described above, and are preferably selected from one or more C₁₋₂₀ alkyl substituents.
q is preferably 1.

The polymer may comprise repeat units that block or reduce conjugation along the polymer chain and thereby increase the polymer bandgap. For example, the polymer may comprise units that are twisted out of the plane of the polymer backbone, reducing conjugation along the polymer backbone, or units that do not provide any conjugation path along the polymer backbone. Exemplary repeat units that reduce conjugation along the polymer backbone are substituted or unsubstituted 1,3-substituted phenylene repeat units, and 1,4-phenylene repeat substituted with a C₁₋₂₀ alkyl group in the 2- and/or 5-position, as described above with reference to formula (V).

The molar percentage of charge transporting repeat units in the polymer, for example repeat units of formula (IV), (V), (VI), (VII), (VIII), may be in the range of up to 75 mol %, optionally in the range of up to 50 mol % of the total number of repeat units of the polymer.

### White OLED

An OLED of the invention may be a white OLED containing a blue light-emitting compound of formula (I) and one or more further light-emitting materials having a colour of emission such that light emitted from the device is white. Further light-emitting materials include red and green light-emitting materials that may be fluorescent or phosphorescent.

The one or more further light-emitting materials may present in the same light-emitting layer as the compound of formula (I) or may be provided in one or more further light-emitting layers of the device.

The light emitted from a white OLED may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-600K.

A green emitting material may have a photoluminescent spectrum with a peak in the range of more than 490 nm up to 580 nm, optionally more than 490 nm up to 540 nm

A red emitting material may optionally have a peak in its photoluminescent spectrum of more than 580 nm up to 630 nm, optionally 585 nm up to 625 nm.

### Polymer Synthesis

Preferred methods for preparation of conjugated polymers, such as polymers comprising one or more of repeat units of formulae (IV), (V), (VI), (VII), (VIII) and (IX) as described above, comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable pi-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups. Likewise, an end group or side group may be bound to the polymer by reaction of a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular copolymers may be prepared when both reactive groups of a first monomer are boron and both reactive groups of a second monomer are halogen.

As alternatives to halides, other leaving groups capable of participating in metal insertion include sulfonic acids and sulfonic acid esters such as tosylate, mesylate and triflate.

### Charge Transporting and Charge Blocking Layers

A hole transporting layer may be provided between the anode and the light-emitting layer or layers. Likewise, an electron transporting layer may be provided between the cathode and the light-emitting layer or layers.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A charge-transporting layer or charge-blocking layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. The crosslinkable group may be provided as a substituent pendant from the backbone of a charge-transporting or charge-blocking polymer. Following formation of a charge-transporting or charge blocking layer, the crosslinkable group may be crosslinked by thermal treatment or irradiation.

If present, a hole transporting layer located between the anode and the light-emitting layers preferably has a HOMO level of less than or equal to 5.5 eV, more preferably around 4.8-5.5 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 2.5-3.5 eV as measured by square wave cyclic voltammetry. A layer of a silicon monoxide or silicon dioxide or other thin dielectric layer having thickness in the range of 0.2-2 nm may be provided between the light-emitting layer nearest the cathode and the cathode. HOMO and LUMO levels may be measured using cyclic voltammetry.

A hole transporting layer may contain a hole-transporting (hetero)arylamine, such as a homopolymer or copolymer comprising hole transporting repeat units of formula (VI). Exemplary copolymers comprise repeat units of formula (VI) and optionally substituted (hetero)arylene co-repeat units, such as phenyl, fluorene or indenofluorene repeat units as described above, wherein each of said (hetero)arylene repeat units may optionally be substituted with one or more substituents such as alkyl or alkoxy groups. Specific co-repeat units include fluorene repeat units of formula (IV) and optionally substituted phenylene repeat units of formula (V) as described above. A hole-transporting copolymer containing repeat units of formula (VI) may contain 25-95 mol % of repeat units of formula (VI).

An electron transporting layer may contain a polymer comprising a chain of optionally substituted arylene repeat units, such as a chain of fluorene repeat units.

More than one hole-transporting layer or more than one electron-transporting layer may be provided. In an embodiment, two or more hole-transporting layers are provided.

### Hole Injection Layers

A conductive hole injection layer, which may be formed from a conductive organic or inorganic material, may be provided between the anode and the light-emitting layer or layers to assist hole injection from the anode into the layer or layers of semiconducting polymer. A hole transporting layer may be used in combination with a hole injection layer.

Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

### Cathode

The cathode is selected from materials that have a workfunction allowing injection of electrons into the light-emitting layer or layers. Other factors influence the selection of the cathode such as the possibility of adverse interactions between the cathode and the light-emitting materials. The cathode may consist of a single material such as a layer of aluminium. Alternatively, it may comprise a plurality of metals, for example a bilayer of a low workfunction material and a high workfunction material such as calcium and aluminium as disclosed in WO 98/10621. The cathode may contain a layer containing elemental barium, for example as disclosed in WO 98/57381, Appl. Phys. Lett. 2002, 81(4), 634 and WO 02/84759. The cathode may contain a thin (e.g. 1-5 nm thick) layer of metal compound between the light-emitting layer(s) of the OLED and one or more conductive layers of the cathode, such as one or more metal layers. Exemplary metal compounds include an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate 1 preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Solution Processing

Suitable solvents for forming solution processable formulations of the light-emitting metal complex of formula (I) and compositions thereof may be selected from common organic solvents, such as mono- or poly-alkylbenzenes and mono- or poly-alkoxybenzenes such as toluene and xylene.

Exemplary solution deposition techniques for forming a light-emitting layer containing a compound of formula (I) include printing and coating techniques such spin-coating, dip-coating, roll-to-roll coating or roll-to-roll printing, doctor blade coating, slot die coating, gravure printing, screen printing and inkjet printing.

Coating methods, such as those described above, are particularly suitable for devices wherein patterning of the light-emitting layer or layers is unnecessary—for example for lighting applications or simple monochrome segmented displays.

Printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

The same coating and printing methods may be used to form other layers of an OLED including (where present) a hole injection layer, a charge transporting layer and a charge blocking layer.

### EXAMPLES

### Emitter Example 1

Emitter Example 1 was prepared according to the following reaction scheme:

### Ligand Synthesis

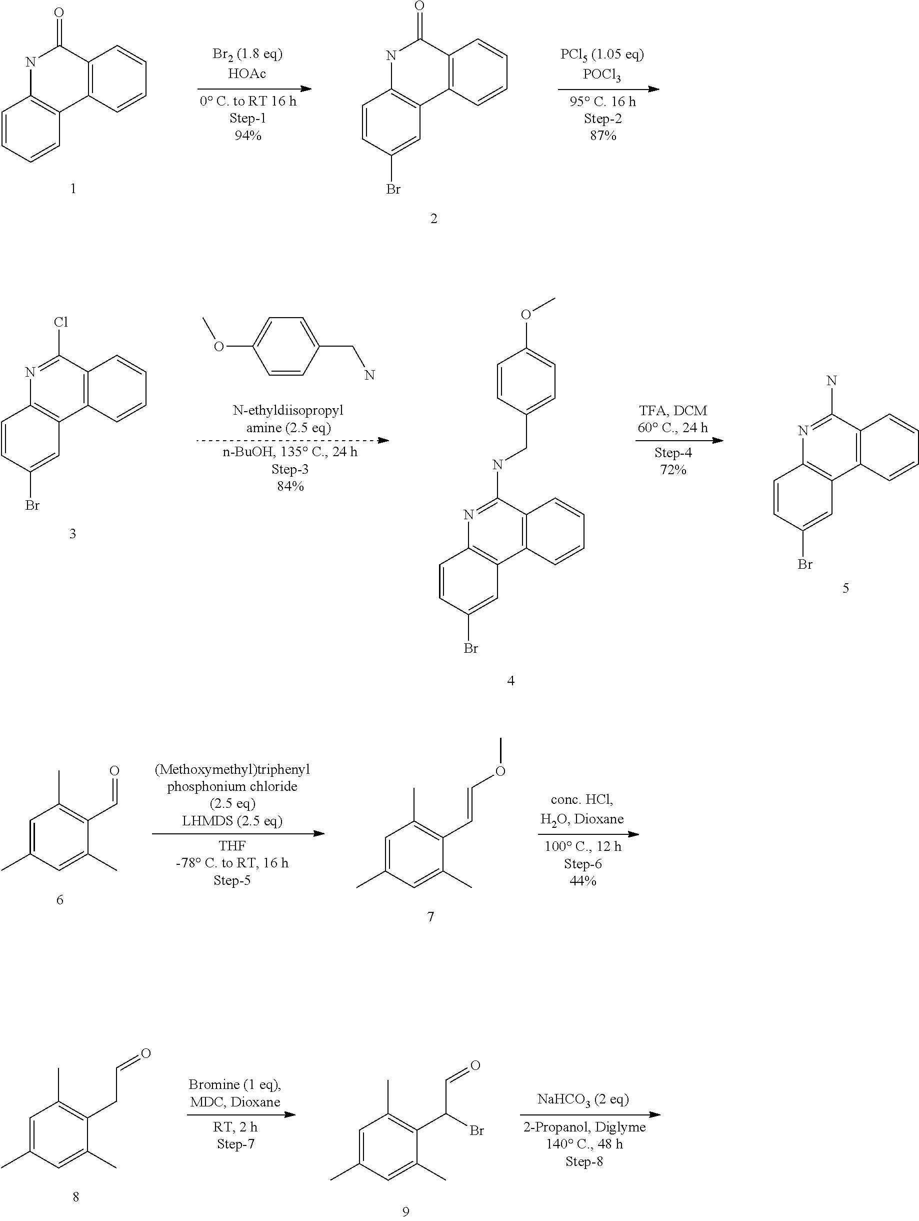

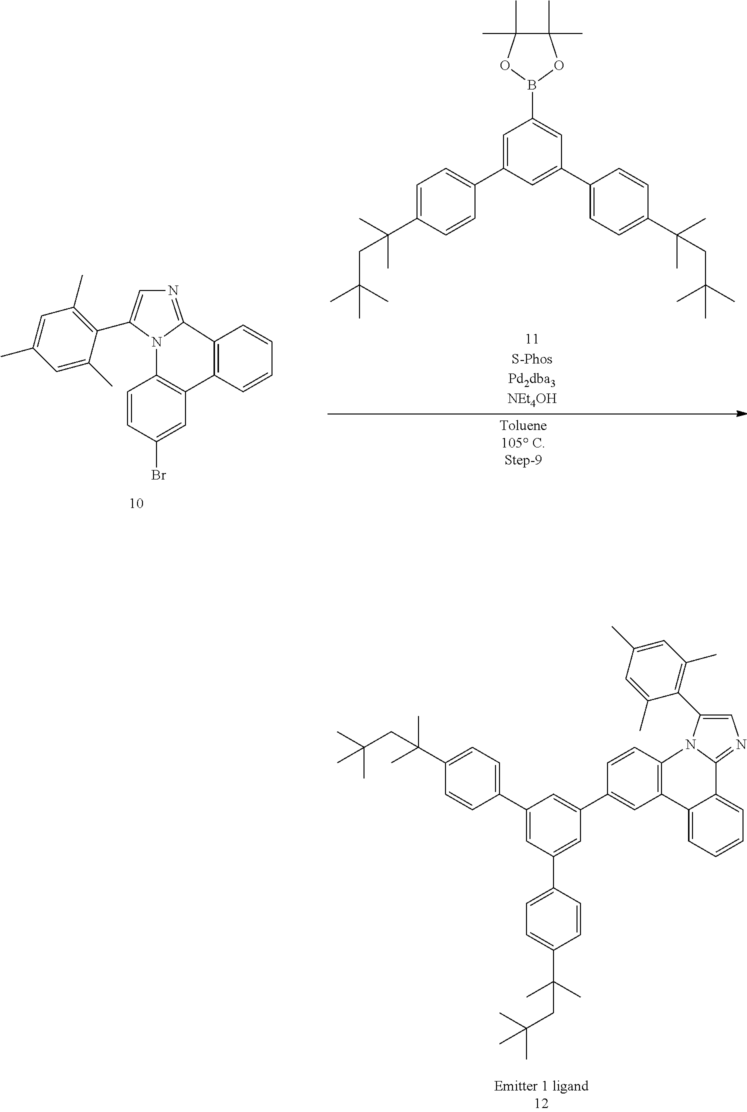 [SMILES: Cc1cc(C)c(-c2cnc3c4ccccc4c4cc(Br)ccc4n23)c(C)c1 ; CC(C)(C)CC(C)(C)c1ccc(-c2cc(B3OC(C)(C)C(C)(C)O3)cc(-c3ccc(C(C)(C)CC(C)(C)C)cc3)c2)cc1 ; Cc1cc(C)c(-c2cnc3c4ccccc4c4cc(-c5cc(-c6ccc(C(C)(C)CC(C)(C)C)cc6)cc(-c6ccc(C(C)(C)CC(C)(C)C)cc6)c5)ccc4n23)c(C)c1]

### Step-1: Synthesis of 2-Bromo-5H-phenanthridin-6-one (2)

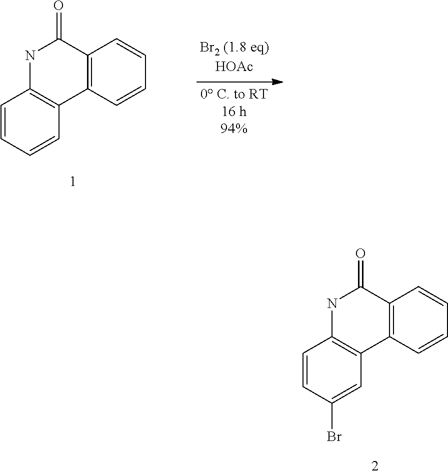 [SMILES: O=c1[nH]c2ccccc2c2ccccc12 ; O=c1[nH]c2ccc(Br)cc2c2ccccc12]

Under nitrogen, 6-(5H)-Phenanthridinone (750 g, 3.841 mol) was taken in acetic acid (7.5 L). The mixture was cooled to 0° C. using an ice bath. Bromine (365 mL, 6.913 mol) was slowly added at 0° C. The reaction was slowly warm to RT and stirred for 16 h. After completion of the reaction, it was carefully added to ice cold water (15 L) and stirred for 30 min. The solid thus obtained was filtered, washed with 10% aqueous sodium thiosulphate solution (4 L) followed by water (4 L). The solid was dried under vacuum to afford 2-Bromo-5H-phenanthridin-6-one (2) as off white solid (990 g, 94%).

¹H-NMR (400 MHz, DMSO-d₆): δ [ppm] δ 7.29 (d, J=8.68 Hz, 1H), 7.64 (dd, J=2.12 Hz, 8.66 Hz, 1H), 7.67-7.69 (m, 1H), 7.83-7.87 (m, 1H), 8.31 (dd, J=1.2 Hz, 7.92 Hz, 1H), 8.56 (d, J=8.16 Hz, 1H), 8.58 (d, J=2.08 Hz, 1H), 11.80 (s, 1H).

### Step-2: Synthesis of 2-Bromo-6-chlorophenanthridine (3)

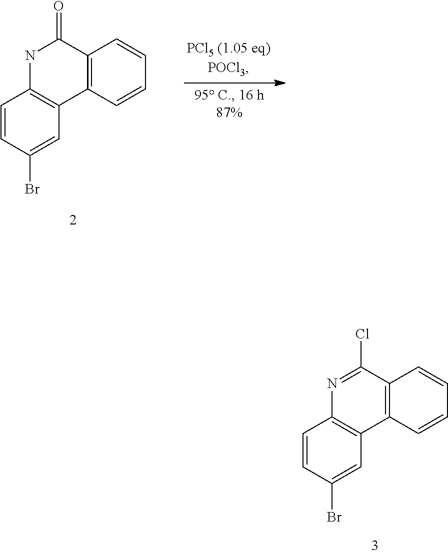 [SMILES: O=c1[nH]c2ccc(Br)cc2c2ccccc12 ; Clc1nc2ccc(Br)cc2c2ccccc12]

Under nitrogen, PCl₅ (958 g, 4.596 mol) was added portion wise to a solution of 2-Bromo-5H-phenanthridin-6-one (1.2 Kg, 4.377 mol) in POCl₃ (7.2 L). The mixture was heated at 95° C. for 16 h. After completion of the reaction, POCl₃ was distilled off under vacuum. The residue was carefully added to ice water (8.5 L) and stirred for an hour. The solid thus obtained was filtered, washed with water and dried under vacuum to afford 2-Bromo-6-chlorophenanthridine (3) (1.12 Kg, 87%).

¹H-NMR (400 MHz, DMSO-d₆): δ [ppm] δ 7.91-7.95 (m, 3H), 8.03-8.07 (m, 1H), 8.42 (d, J=7.64 Hz, 1H), 8.96 (d, J=8.28 Hz, 1H), 9.04 (s, 1H).

### Step-3: Synthesis of Intermediate 4

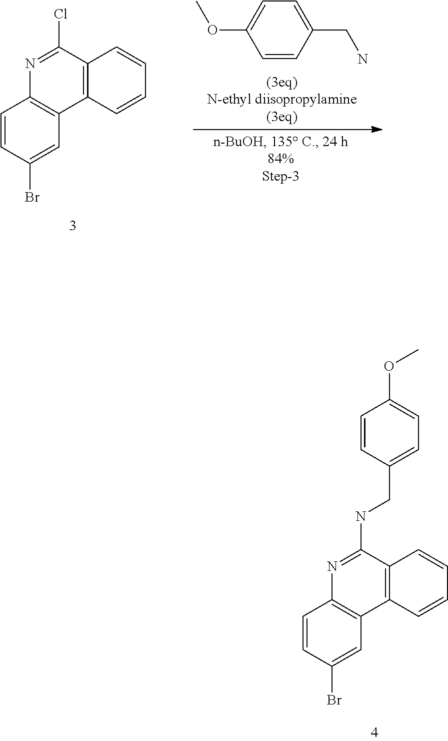

Under nitrogen, a mixture of 2-bromo-6-chlorophenanthridine (3) (1.58 kg, 5.4 mol), 4-methoxybenzylamine (2.22 kg, 16.2 mol) and N-ethyldiisopropyl amine (2.793 L, 16.2 mol) in n-Butanol (15 L) was heated at 135° C. for 24 h. After completion of the reaction, cooled to RT and filtered. The solid was washed with methanol and dried under vacuum to afford Intermediate 4 (1.8 Kg, 84%).

¹H-NMR (400 MHz, DMSO-d₆): δ [ppm] δ 3.70 (s, 3H), 4.77 (s, 2H), 6.87 (d, J=6.36 Hz, 2H), 7.38 (d, J=5.88 Hz, 2H), 7.47-7.49 (m, 1H), 7.60-7.84 (m, 3H), 8.25-8.29 (m, 1H), 8.42-8.44 (m, 1H), 8.64-8.71 (m, 2H).

### Step-4: Synthesis of 2-Bromo-6-aminophenanthridine (5)

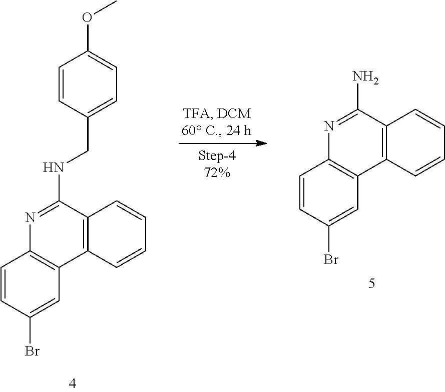 [SMILES: COc1ccc(CNc2nc3ccc(Br)cc3c3ccccc23)cc1 ; Nc1nc2ccc(Br)cc2c2ccccc12]

Under nitrogen, a mixture of Intermediate 4 (1.2 Kg, 3.051 mol), TFA (7.2 L) in DCM (7.2 L) was heated to 60° C. and stirred for 24 h. After completion of the reaction, cooled to RT and TFA was removed in a rotary evaporator. The residue was dissolved in ethyl acetate (8 L), washed with 10% aqueous sodium carbonate solution (5 L), water (5 L), dried over sodium sulphate and concentrated. The residue thus obtained was triturated with MTBE (2 L) to get 2-Bromo-6-aminophenanthridine (5) (600 g, 72%).

¹H-NMR (400 MHz, DMSO-d₆): δ [ppm] δ 7.23 (br, s, 2H), 7.45 (d, J=8.68 Hz, 1H), 7.62 (dd, J=2.20 Hz, 8.68 Hz, 1H), 7.69-7.73 (m, 1H), 7.82-7.86 (m, 1H), 8.36 (d, J=7.80 Hz, 1H), 8.65 (d, J=2.20 Hz, 1H), 8.70 (d, J=8.08 Hz, 1H).

### Step-5: Synthesis of Intermediate 7

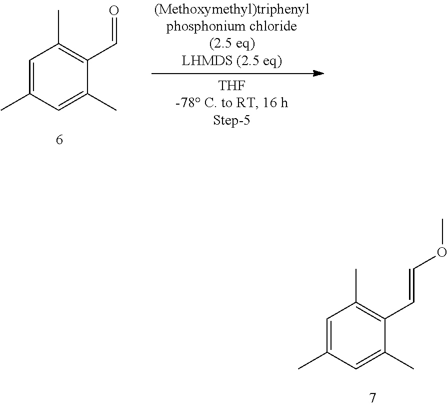

Under nitrogen, (Methoxymethyl)triphenylphosphonium chloride (1.734 Kg, 5.05 mol) was taken in THF (5 L) and cooled to −78° C. using dry ice/acetone bath. LiHMDS (5 L, 1.0M in THF) was added to the reaction mixture at −78° C. The reaction mixture slowly allowed to 0° C. and stirred for 30 min. It was again cooled to −78° C. 2,4,6-Trimethyl benzaldehyde (300 g, 2.02 mol) in THF (5 L) was added to the reaction mixture at −78° C. The mixture was slowly allowed to warm to RT and stirred for 16 h. After completion of the reaction, the mixture was quenched with ammonium chloride solution (3 L) and extracted with EtOAc (3 L×2). The combined organic layer was dried over sodium sulphate and concentrated. The crude product was purified by column chromatography (silica gel, 60-120 mesh) using 2% EtOAc in hexane as an eluent to afford Intermediate 7 (350 g). It was used as such in next step.

### Step-6: Synthesis of 2,4,6-Trimethylphenyl acetaldehyde (8)

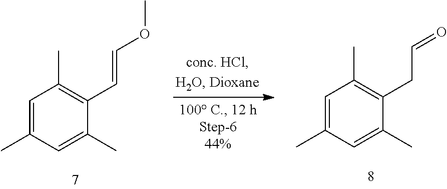

Under nitrogen, a mixture of Intermediate 7 (700 g, 3.971 mol), conc. HCl (2.1 L) and water (3.3 L) in 1,4-dioxane (2.1 L) was heated at 100° C. for 12 h. After completion of the reaction, dioxane was removed in a rotary evaporator and the aqueous phase was extracted with ethyl acetate (5 L×2). The combined organic layer was washed with brine (1.5 L), dried over sodium sulphate and concentrated. The crude product was purified by column chromatography (silica gel, 60-120 mesh) using 8% of EtOAc in hexane as an eluent to afford 2,4,6-Trimethylphenyl acetaldehyde (8) (280 g, 44%).

¹H-NMR (300 MHz CDCl₃): δ [ppm] δ 2.26 (s, 6H), 2.28 (s, 3H), 3.73 (d, J=2.01 Hz, 2H), 6.92 (s, 2H), 9.66 (t, J=2.10 Hz, 1H).

### Step-7: Synthesis of Intermediate 9

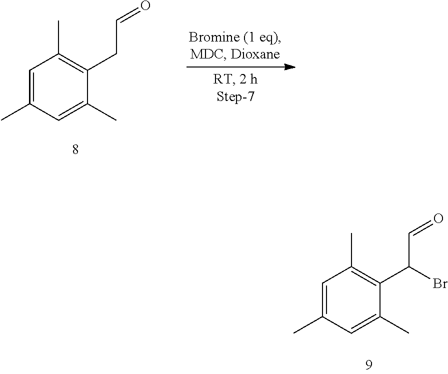

Under nitrogen, 2,4,6-Trimethylphenyl acetaldehyde (400 g, 2.465 mol) was dissolved in DCM (3.25 L) and 1,4-Dioxane (6.2 L). A solution of bromine (127 mL, 2.465 mol) in DCM (3.25 L) was added to the above solution at RT. The reaction mixture was stirred for 2 h at RT. After completion of the reaction, sodium thiosulphate solution (3 L) was added. It was extracted with DCM (3 L), washed with water (2.5 L), dried over sodium sulphate and concentrated to afford Intermediate 9 (620 g). The crude product was taken for the next step without further purification.

¹H-NMR (300 MHz, CDCl₃): δ [ppm] δ 2.27 (s, 3H), 2.29 (s, 6H), 5.76 (s, 1H), 6.90 (s, 2H), 9.72 (s, 1H).

### Step-8: Synthesis of 7-Bromo-3-(2,4,6-trimethylphenyl)imidazo[1,2-f]phenanthridine (10)

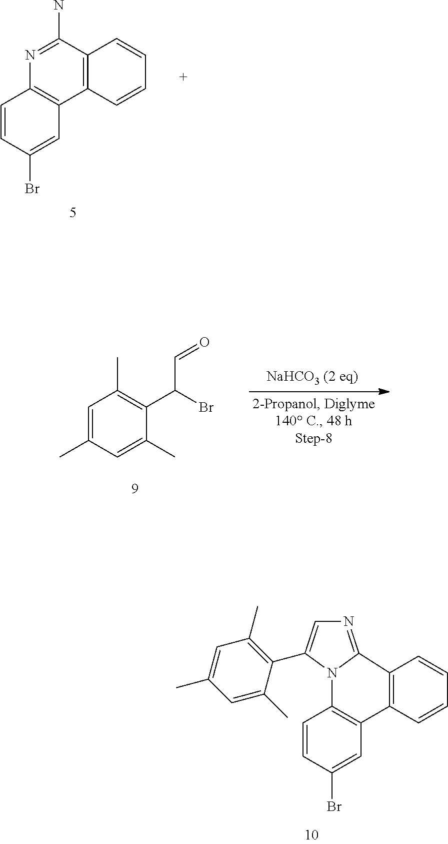 [SMILES: Nc1nc2ccc(Br)cc2c2ccccc12 ; Cc1cc(C)c(C(Br)C=O)c(C)c1 ; Cc1cc(C)c(-c2cnc3c4ccccc4c4cc(Br)ccc4n23)c(C)c1]

Under nitrogen, a mixture of 2-Bromo-6-aminophenanthridine (5) (702.2 g, 2.571 mol) and Intermediate 9 (620 g, 2.571 mol) in 2-propanol (6.2 L) was heated to 95° C. for 24 h. NaHCO₃ (330 g, 5.142 mol) and diglyme (6.2 L) were added and heated at 140° C. for 48 h. After the completion of the reaction water (10 L) was added and stirred for an hour. The solid thus obtained was filtered and washed with water, dried to get crude 10. The crude product was purified by column chromatography (silica gel, 60-120 mesh) using 7% EtOAc in hexane as an eluent to afford 10 with 98.8% HPLC purity. Another 400 g of Intermediate 9 was converted to 10 following the above procedure and the crude product obtained from both the batches were combined and crystallized. Recrystalization: The product thus obtained was taken in toluene:hexane (1:2) mixture and heated to 80° C. for an hour. It was cooled to room temperature and filtered to get 520 g of 10 with 99.61% HPLC purity.

¹H-NMR (400 CDCl₃): δ [ppm] δ 2.03 (s, 6H), 2.43 (s, 3H), 7.07 (s, 2H), 7.22 (d, J=9.04 Hz, 1H), 7.35 (dd, J=2.16 Hz and 9.08 Hz, 1H), 7.38 (s, 1H), 7.66-7.74 (m, 2H), 8.33 (d, J=7.80 Hz, 1H), 8.58 (d, J=2.12 Hz, 1H), 8.76 (d, J=7.28 Hz, 1H).

### Step-9: Synthesis of Emitter 1 ligand (12)

7-Bromo-3-(2,4,6-trimethylphenyl)imidazo[1,2-f]phenanthridine 10 (10.0 g, 24 mmol) and Intermediate 11 (16.84 g, 29 mmol, 1.2 equivalents) were placed in a 500 mL 3-neck flask fitted with a reflux condenser and overhead stirrer. Toluene (150 mL) was added and the mixture degassed for 1 h. The reaction mixture was then heated with stirring to 85° C. Pd₂dba₃ (0.11 g, 0.12 mmol, 0.005 equiv) and SPhos (0.099 g, 0.24 mmol, 0.005 equiv) were added as solids, followed by the degassed solution of Et₄NOH (20% w/v aqueous solution) (70 mL, 96 mmol, 4 equiv). The mixture was then heated to 105° C. with stirring (500 rpm) for 24 h. The reaction was allowed to cool to room temperature and the organic layer separated. The aqueous layer was extracted with dichloromethane (2×100 mL). Organic fractions were combined and concentrated under reduced pressure to give an orange coloured solid of ca. 90% HPLC purity. R_{f}=0.42 (20% EtOAc in hexanes) on silica TLC plate. The crude product was purified by automatic column chromatography on silica using a gradient of EtOAc in hexanes to yield 17.59 g, 93% yield. HPLC purity 99.8%.

¹H NMR (CDCl₃, 610 MHz): δ [ppm] 8.78 (d, J=7.7 Hz, 1H), 8.76 (s, 1H), 8.52 (d, J=7.7 Hz, 1H), 7.85 (s, 1H), 7.83 (s, 2H), 7.72-7.67 (m, 2H), 7.64 (d, J=8.5 Hz, 4H), 7.60 (d, J=8.8 Hz, 1H), 7.49 (d, J=8.5 Hz, 4H), 7.44 (d, J=8.8 Hz, 1H), 7.40 (s, 1H), 7.09 (s, 2H), 2.44 (s, 3H), 2.08 (s, 6H), 1.81 (s, 4H), 1.43 (s, 12H), 0.78 (s, 18H).

### Emitter Example 1

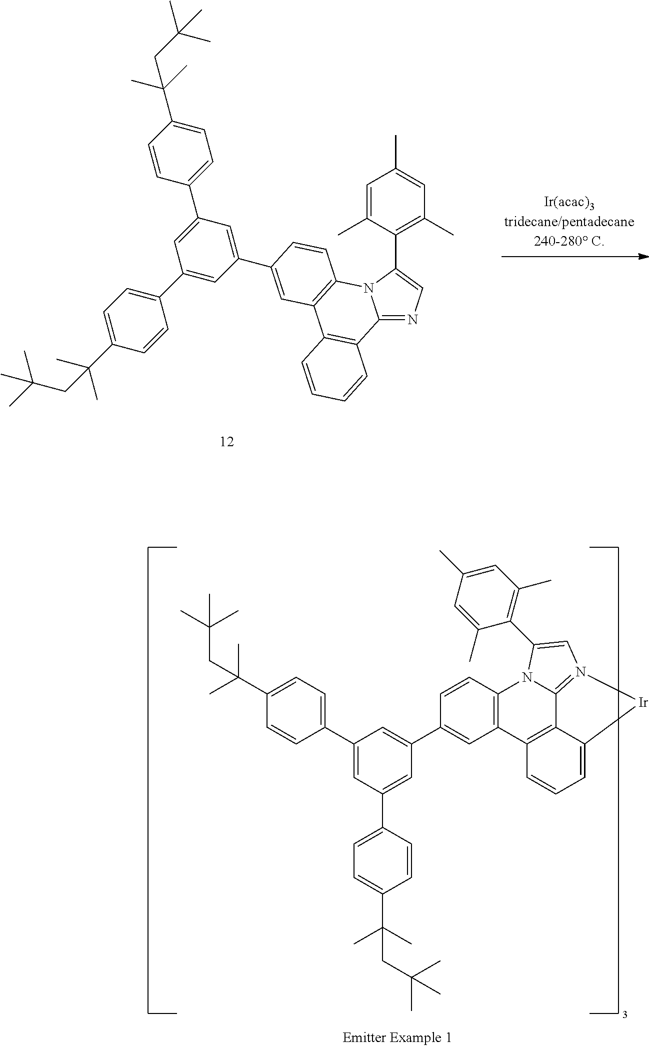

Emitter 1 ligand (12) (5.10 g, 6.46 mmol) and Ir(acac)₃ (0.708 g, 1.45 mmol) were placed in a 25 mL Schlenk flask equipped with an air condenser and magnetic stirrer bar. Under nitrogen, tridecane (1.5 mL) was added and the mixture was heated to 260-280° C. for 3 days. After cooling to RT, the brown solid is dissolved in dichloromethane and purified by column chromatography on silica using a gradient of dichloromethane in hexanes (starting from 20% dichloromethane and increasing to 35%). The resulting yellow solid was dissolved in the minimum of dichloromethane and precipitated by the addition of MeOH (200 mL). Emitter Example 1 was collected and dried in a vacuum oven at 50° C. for 24 h. 2.06 g, 49% yield, 98.95% HPLC purity).

¹H NMR (CDCl₃, 600 MHz): δ [ppm] 8.77 (s, 3H), 7.82 (s, 9H), 7.80 (d(broad), J=6.0 Hz, 3H), 7.63 (d, J=8.3 Hz, 12H), 7.53 (d, J=8.7 Hz, 3H), 7.48 (d, J=8.3 Hz, 12H), 7.24 (d, J=8.8 Hz, 3H), 7.21 (t, J=7.6 Hz, 3H), 7.16 (s(broad), 3H), 7.03 (s, 3H), 6.99 (s, 3H), 6.85 (s, 3H), 2.39 (s, 9H), 2.10 (s, 9H), 1.90 (s, 9H), 1.80 (s, 12H), 1.42 (s, 36H), 0.77 (s, 54H).

### Materials

Photoluminescence and electroluminescence measurements of host-emitter compositions where made wherein the emitter was selected from Emitter Example 1, Comparative Emitter 1 and Comparative Emitter 2, and the host was selected from in a polymeric hosts prepared by Suzuki polymerisation as described in WO 00/53656 of monomers set out in Table 1.

TABLE 1
monomers for polymer hosts

| | Boronic acid monomer | Halo monomer |
|---|---|---|
| Host polymer | (mol %) | (mol %) |
| Host polymer 1 | Monomer 3 (35) | Monomer 6 (50) |
| | Monomer 1 (15) | |
| Host polymer 2 | Monomer 1 (35) | Monomer 4 (50) |
| | Monomer 2 (15) | |
| Host polymer 3 | Monomer 1 (50) | Monomer 5 (50) |

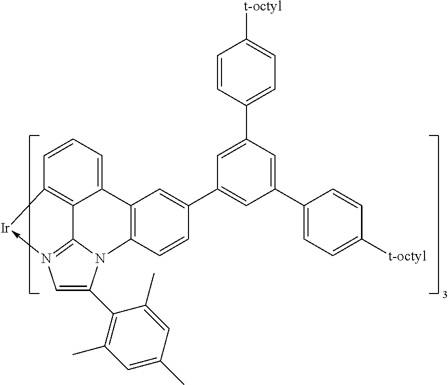

### Emitter Example 1

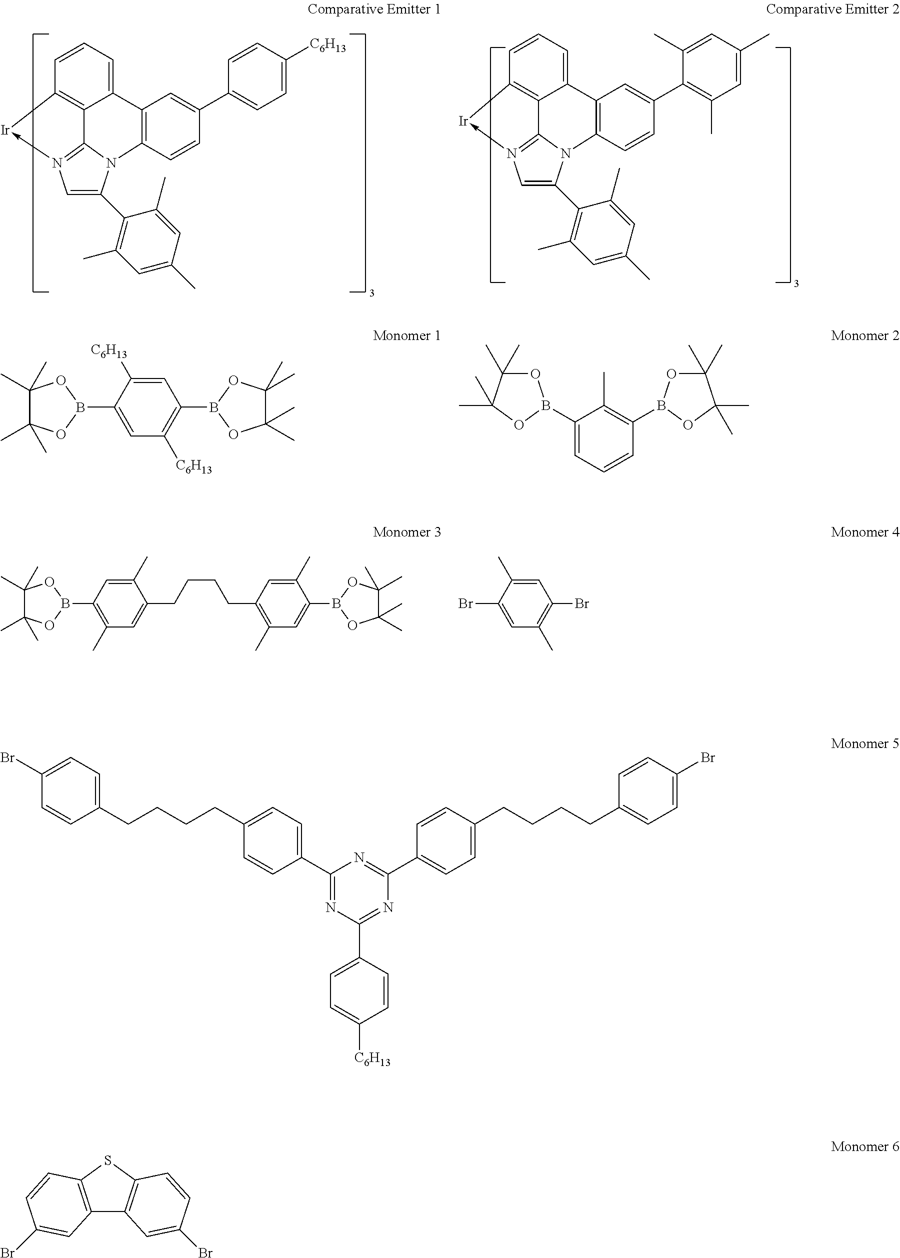

### Photoluminescence Quantum Yield (PLQY)

For PLQY measurements films were spun from a suitable solvent (for example alkylbenzene, halobenzene, alkoxybenzene) on quartz disks to achieve transmittance values of 0.3-0.4. A particularly preferred solvent is ortho-xylene. Measurements were performed under nitrogen in an integrating sphere connected to Hamamatsu C9920-02 with Mercury lamp E7536 and a monochromator for choice of exact wavelength.

TABLE 2
photoluminescence measurements

| | | Host:Emitter | | | |
|---|---|---|---|---|---|
| Host polymer | Emitter | weight ratio | PLQY (%) | CIE x | CIE y |
| Host polymer1 | Comparative | 95:5 | 35.5 | 0.163 | 0.276 |
| | Emitter 1 | | | | |
| Host polymer 1 | Comparative | 95:5 | 36.2 | 0.162 | 0.257 |
| | Emitter 2 | | | | |
| Host polymer 1 | Emitter | 95:5 | 46.8 | 0.16 | 0.279 |
| | Example 1 | | | | |
| Host polymer 1 | Comparative | 64:36 | 13.8 | 0.186 | 0.317 |
| | Emitter 1 | | | | |
| Host polymer 1 | Comparative | 64:36 | 13 | 0.211 | 0.316 |
| | Emitter 2 | | | | |
| Host polymer 1 | Emitter | 64:36 | 27.6 | 0.174 | 0.317 |
| | Example 1 | | | | |
| Host polymer 2 | Comparative | 95:5 | 40 | 0.16 | 0.269 |
| | Emitter 1 | | | | |
| Host polymer 2 | Comparative | 95:5 | 35.9 | 0.163 | 0.254 |
| | Emitter 2 | | | | |
| Host polymer 2 | Emitter | 95:5 | 46.8 | 0.16 | 0.279 |
| | Example 1 | | | | |

As shown in Table 2, Emitter Example 1 provides a higher PLQY in different hosts and at low (5 weight %) and high (36 weight %) concentrations as compared to either Comparative Emitter 1 or Comparative Emitter 2.

### Colour Point

A change in the colour of emission of a metal complex has been observed upon dendronisation of the metal complex. For example, attachment a dendron to a phenyltriazole metal complex has the effect of shifting emission to a longer wavelength.

TABLE 3
PLQY of emitters at 5 weight % in host matrix

| Emitter | Host | λₘₐₓ (nm) | Colour shift (nm) | PLQY (%) |
|---|---|---|---|---|
| Comparative | Host | 464 | | 40 |
| emitter 1 | Polymer 2 | | | |
| Emitter | Host | 464 | 0 nm | 41 |
| Example 1 | Polymer 2 | | | |
| Phenly | Host | 468 | | 84 |
| Triazole | Polymer 3 | | | |
| Emitter 1 | | | | |
| Phenyl | Host | 476 | 8 nm | 85 |
| Triazole | Polymer 3 | | | |
| Emitter 2 | | | | |

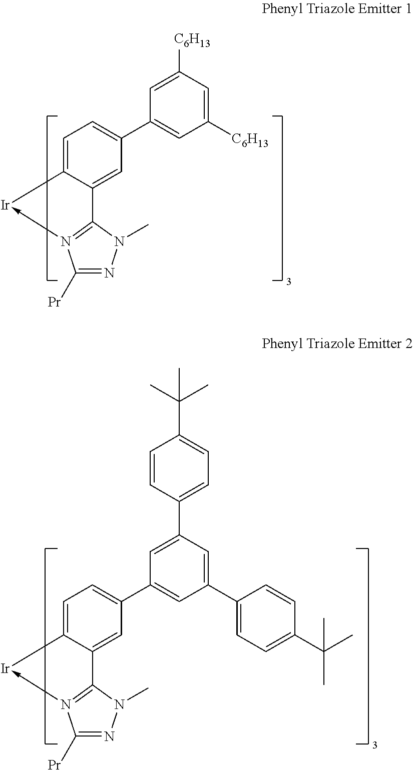

The present inventors have surprisingly found that the colour of Emitter Example 1 is not significantly affected by the presence of the dendrimer, as shown in Table 2. By comparison, a 8 nm bathochromic shift is observed for dendrimer emitter, Phenyl Triazole Emitter 2 compared to non-dendrimer emitter, Phenyl Triazole Emitter 1.

### Device Example 1

A white organic light-emitting device having the following structure was prepared:

### ITO/HIL/HTL/LEL/Cathode

wherein ITO is an indium-tin oxide anode; HIL is a hole-injecting layer comprising a hole-injecting material, HTL is a hole-transporting layer, and LEL is a light-emitting layer containing light-emitting metal complexes and a host polymer.

A substrate carrying ITO was cleaned using UV/Ozone. A hole injection layer was formed to a thickness of about 35 nm by spin-coating an aqueous formulation of a hole-injection material available from Plextronics, Inc. A red-emitting hole transporting layer was formed to a thickness of about 22 nm by spin-coating a crosslinkable red-emitting hole-transporting polymer and crosslinking the polymer by heating.

The red-emitting hole transporting polymer was formed by Suzuki polymerisation as described in WO 00/53656 of the following monomers:

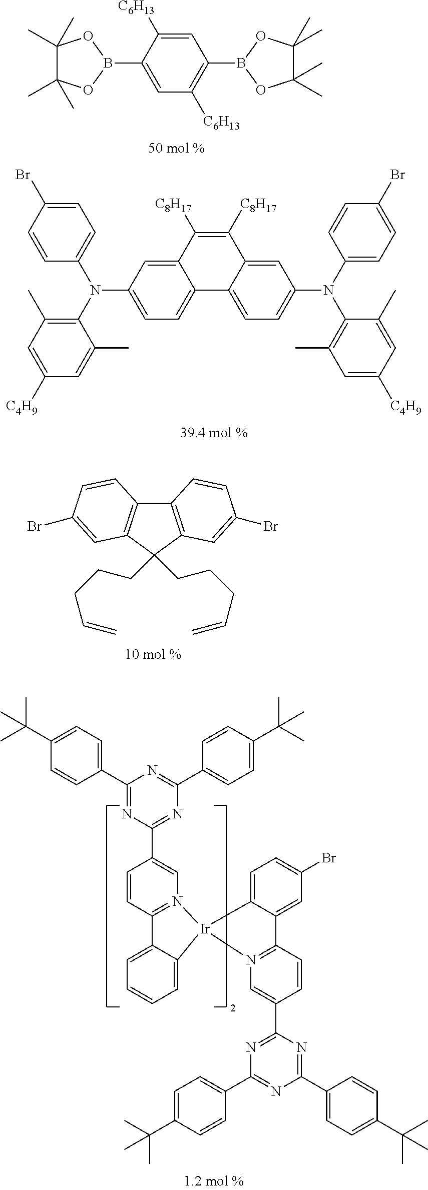

The hole transport polymer has the following molecular weight characteristics (GPC relative to polystyrene standard, in Dalton): Mw 129,000, Mp 128,000, Mn 37,000, Pd 3.53.

A green and blue light emitting layer was formed by depositing a light-emitting composition containing Host Polymer 3 doped with Emitter Example 1 (blue light-emitting metal complex) and Green Phosphorescent Emitter 1, illustrated below, in a weight ratio of Host Polymer 3:Emitter Example 1:Green Phosphorescent Emitter 1 of 84:15:1) to a thickness of about 75 nm by spin-coating. A cathode was formed by evaporation of a first layer of a sodium fluoride to a thickness of about 2 nm, a second layer of aluminium to a thickness of about 100 nm and a third layer of silver to a thickness of about 100 nm.

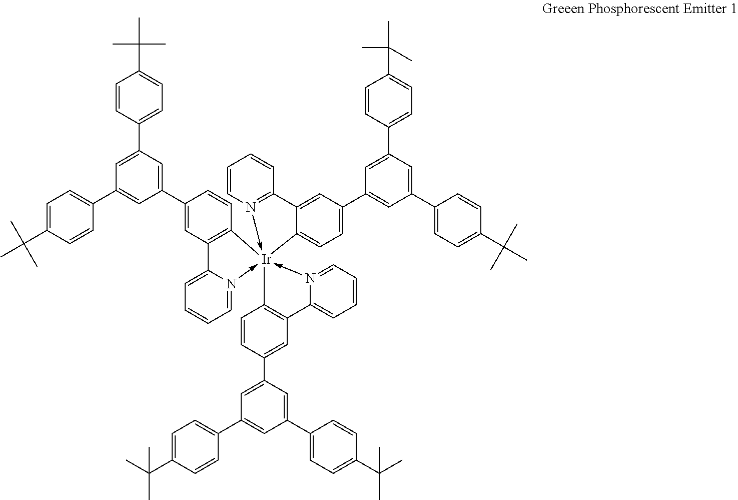

### Comparative Device 1

A device was prepared as described in Device Example 1 except that Emitter Example 1 was replaced with Comparative Emitter 1

With reference to FIG. 2, the electroluminescent spectra of Comparative Device 1 and Device Example 1 are similar.

The time taken for brightness of Comparative Device 1 and Device Example 1 to fall to 70% of an initial brightness of 1000 cd/m2 was measured (T70). The T70 value of Device Example 1 was more than three times that of Comparative Device 1.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A phosphorescent compound of formula (I): 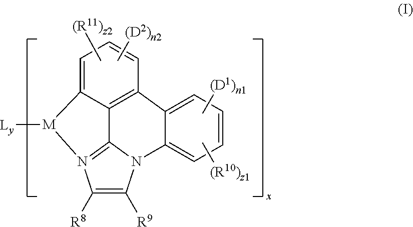
wherein:
M is a transition metal;
L in each occurrence is independently a mono- or poly-dentate ligand;
R⁸, R⁹, R¹⁰ and R¹¹ are each independently H or a substituent;
D¹ and D² are each independently a dendron;
x is at least 1;
y is 0 or a positive integer;
z1 and z2 are each independently 0 or a positive integer; and
n1 and n2 are each independently 0 or 1 with the proviso that at least one of n1 and n2 is 1.

2. A compound according to claim 1 wherein M is selected from iridium, platinum, osmium, palladium, rhodium and ruthenium.

3. A compound according to claim 1 wherein y is 0.

4. A compound according to claim 3 wherein x is 3.

5. A compound according to claim 1 wherein D¹ and D² are each independently selected from dendrons of formula (III): 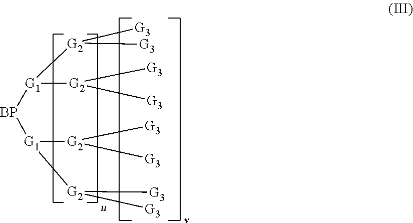
wherein u is 0 or 1; v is 0 if u is 0 or may be 0 or 1 if u is 1; BP represents a branching point through which the dendron D¹ or D² is bound in the compound of formula (I) and G₁, G₂ and G₃ respectively represent first, second and third generation dendron branching groups.

6. A compound according to claim 5 wherein BP is a substituted or unsubstituted arylene or heteroarylene group.

7. A compound according to claim 6 wherein G₁, G₂ and G₃ are selected from substituted or unsubstituted arylene or heteroarylene groups.

8. A compound according to claim 1 wherein R⁸ and R⁹ are selected from the group consisting of:
H;
aryl or heteroaryl that may be unsubstituted or substituted with one or more substituents; and
branched, linear or cyclic C₁₋₂₀ alkyl wherein non-adjacent C atoms of the C₁₋₂₀ alkyl may be replaced with —O—, —S—, —NR³—, —SiR³₂- or —COO— and one or more H atoms may be replaced with F, wherein R³ is H or a substituent.

9. A compound according to claim 5 wherein R⁹ is aryl or heteroaryl that may be unsubstituted or substituted with one or more substituents.

10. A compound according to claim 1 wherein R¹⁰ and R¹¹ in each occurrence is independently selected from the group consisting of:
aryl or heteroaryl that may be unsubstituted or substituted with one or more substituents; and
branched, linear or cyclic C₁₋₂₀ alkyl wherein non-adjacent C atoms of the C₁₋₂₀ alkyl may be replaced with —O—, —S—, —NR³—, —SiR³₂- or —COO— and one or more H atoms may be replaced with F, wherein R³ is H or a substituent.

11. A compound according to claim 1 wherein n1=1

12. A compound according to claim 11 of formula (Ia):

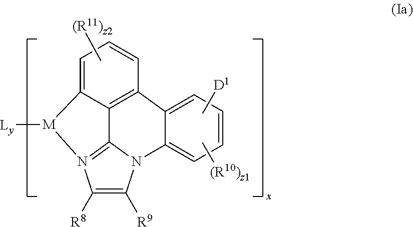

13. A compound according to claim 1 wherein n2=1.

14. A compound according to claim 13 of formula (Ib):

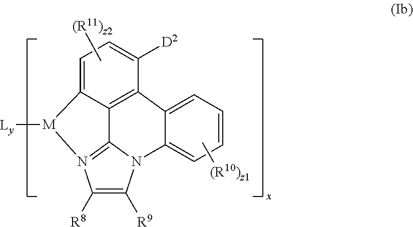

15. A compound according to claim 1 wherein the compound has a photoluminescent spectrum having a peak wavelength in the range of 400-490 nm, preferably 460-480 nm.

16. A composition comprising a host material and a compound according to claim 1.

17. A composition according to claim 16 wherein the host material is a polymer.

18. A composition according to claim 17 wherein the host polymer comprises a repeat unit comprising triazine.

19. A composition according to claim 16 wherein the phosphorescent compound is blended with the host material and is provided in an amount in the range of 0.5-50 wt % relative to the host material.

20. An organic light-emitting device comprising an anode, a cathode and a light-emitting layer between the anode and cathode wherein the light-emitting layer comprises a compound according to claim 1.
